(19) United States
(12) Patent Application Publication
(10) Pub. No.: US 2008/0000768 A1
(43) Pub. Date: Jan. 3, 2008

(54) Electrically Coupled Target Panels

(76) Inventors: Bradley O. Stimson, Mone Sereno, CA (US); Makoto Inagawa, Palo Alto, CA (US); Hienminh Huu Le, San Jose, CA (US); John M. White, Hayward, CA (US)

Correspondence Address: PATTERSON & SHERIDAN, LLP, 3040 POST OAK BOULEVARD, SUITE 1500, HOUSTON, TX, 77056, US

(21) Appl. No.: 11/428,226

(22) Filed: Jun. 30, 2006

(51) Int. Cl. C23C 14/32; C23C 14/00

(52) U.S. Cl. 204/192.1; 204/298.12

(57) ABSTRACT

A method and apparatus for electrically coupling a plurality of target together is disclosed. Individually powered targets allow greater control over depositing during a sputtering process. By individually powering the targets, different power levels may be applied to different targets. The targets may additionally be coupled together with a resistor. The resistor allows the targets to have a more controlled power level.

### BACKGROUND OF THE INVENTION

1. Field of the Invention

Embodiments of the present invention generally relate to a sputtering target assembly and a method of sputtering in a physical vapor deposition (PVD) system.

2. Description of the Related Art

PVD using a magnetron is one method of depositing material onto a substrate. During a PVD process a target may be electrically biased so that ions generated in a process region can bombard the target surface with sufficient energy to dislodge atoms from the target. The process of biasing a target to cause the generation of a plasma that causes ions to bombard and remove atoms from the target surface is commonly called sputtering. The sputtered atoms travel generally toward the substrate being sputter coated, and the sputtered atoms are deposited on the substrate. Alternatively, the atoms react with a gas in the plasma, for example, nitrogen, to reactively deposit a compound on the substrate. Reactive sputtering is often used to form thin barrier and nucleation layers of titanium nitride or tantalum nitride on the substrate.

Direct current (DC) sputtering and alternating current (AC) sputtering are forms of sputtering in which the target is biased to attract ions towards the target. The target may be biased to a negative bias in the range of about −100 to −600 V to attract positive ions of the working gas (e.g., argon) toward the target to sputter the atoms. Usually, the sides of the sputter chamber are covered with a shield to protect the chamber walls from sputter deposition. The shield may be electrically grounded and thus provide an anode in opposition to the target cathode to capacitively couple the target power to the plasma generated in the sputter chamber.

To deposit thin films over large area substrates such as glass substrates, flat panel display substrates, solar panel substrates, and other suitable substrates, a sputtering target must be of substantial size. Producing a large area sputtering target can be quite expensive. Additionally, as the size of the sputtering target increases, it becomes increasingly more difficult to transport a sputtering target.

Therefore, there is a need in the art to provide smaller sputtering targets in PVD chambers, but still have the capacity to deposit uniform films on large area substrates.

### SUMMARY OF THE INVENTION

The present invention generally comprises a sputtering target assembly and a method of sputtering. Individually powered targets allow greater control over depositing during a sputtering process. By individually powering the targets, different power levels may be applied to different targets. The targets may additionally be coupled together with a resistor. The resistor allows the targets to have a more controlled power level.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 is a cross sectional view of a PVD apparatus according to one embodiment of the invention.

FIG. 2 is a schematic view of the electrical coupling for a target assembly according to one embodiment of the invention.

FIG. 3 is a schematic view of the electrical coupling for a target assembly according to another embodiment of the invention.

FIG. 4 is a cross sectional view of electrical coupling of a power source to a sputtering target according to one embodiment of the present invention.

To facilitate understanding, identical reference numerals have been used, where possible, to designate identical elements that are common to the figures. It is contemplated that elements disclosed in one embodiment may be beneficially utilized on other embodiments without specific recitation.

### DETAILED DESCRIPTION

The present invention generally comprises a sputtering target assembly and a method of sputtering. Individually powered targets allow greater control over depositing during a sputtering process. By individually powering the targets, different power levels may be applied to different targets. The targets may additionally be coupled together with a resistor. The resistor allows the targets to have a more controlled power level.

The invention is illustratively described and may be used in a physical vapor deposition system for processing large area substrates, such as a PVD system, available from AKT®, a subsidiary of Applied Materials, Inc., Santa Clara, Calif. However, it should be understood that the sputtering target may have utility in other system configurations, including those systems configured to process large area round substrates. An exemplary system in which the present invention can be practiced is described in U.S. patent application Ser. No. 11/225,922, filed Sep. 13, 2005, which is hereby incorporated by reference in its entirety.

As the size of substrates increases, so must the size of the sputtering target. For flat panel displays and solar panels, sputtering targets having a length of greater than 1 meter are not uncommon. Producing a unitary sputtering target of substantial size from an ingot can prove difficult and expensive. For example, it is difficult to obtain large molybdenum plates (i.e., 1.8 m×2.2 m×10 mm, 2.5 m×2.8 m×10 mm, etc.) and quite expensive. Producing a large area molybdenum target requires a significant capital investment. A large area (i.e., 1.8 m×2.2 m×10 mm) one piece molybdenum target may cost as much as $15,000,000 to produce. Therefore, for cost considerations alone, it would be beneficial to utilize a plurality of smaller targets, but still achieve the deposition uniformity of a large area sputtering target. The plurality of targets may be the same composition or a different composition.

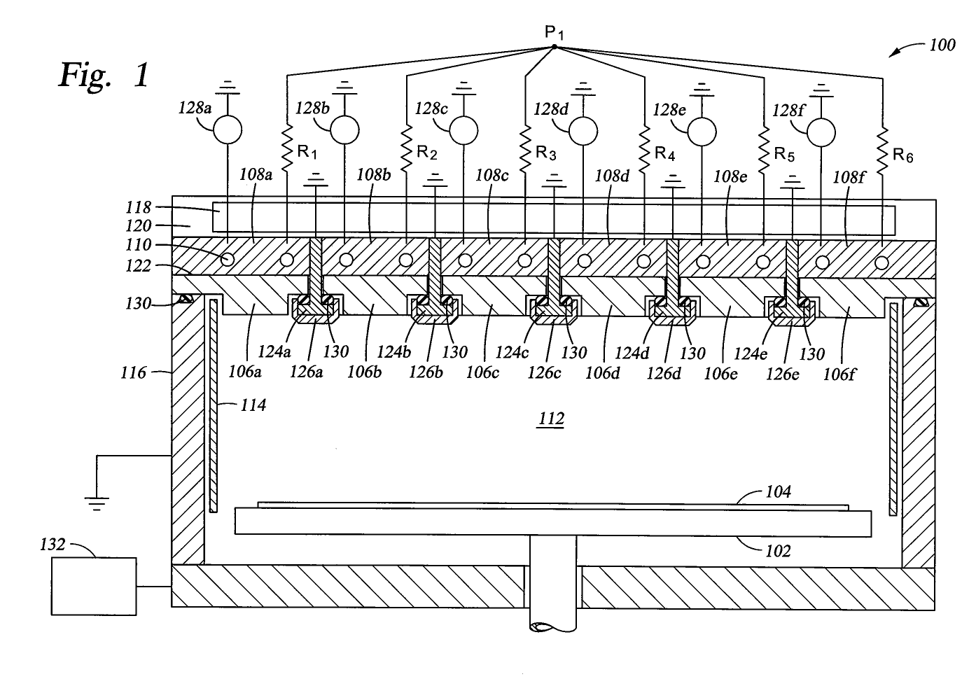

FIG. 1 is a cross sectional view of a PVD apparatus 100 according to one embodiment of the invention. The apparatus 100 comprises a substrate 104 supported on a susceptor 102 contained within the chamber walls 116 of the apparatus 100. The chamber walls 116 are grounded. The substrate 104 sits opposite a plurality of sputtering targets 106a-106f. Between the substrate 104 and the targets 106a-106f is the processing region 112. The chamber walls 116 are shielded from deposition by a shield 114.

In one embodiment, each sputtering target 106a-106f has a corresponding backing plate 108a-108f. In another embodiment, each sputtering target 106a-106f is coupled with a single, common backing plate. While the invention will be described with reference to the former embodiment, it is to be understood that the descriptions are equally applicable to the single, common backing plate embodiment.

Within the backing plates 108a-108c are cooling channels 110. Cooling fluid is flowed through the cooling channels to control the temperature of the backing plates 108a-108f and hence, the sputtering targets 106a-106f. The cooling fluid may be any conventional cooling fluid known in the art. In one embodiment, the cooling fluid is water. In another embodiment, the cooling fluid is in the gaseous state.

A magnetron 118 is positioned in a magnetron chamber 120 that lies behind the backing plates 108a-108f. The magnetron 118 may be a stationary magnetron assembly or a movable magnetron assembly. In one embodiment, the magnetron 118 is a plurality of magnetron assemblies wherein the number of magnetrons corresponds to the number of targets 106a-106f. When the number of magnetrons 118 corresponds to the number of targets 106a-106f, the magnetic field across each individual target may be controlled and adjusted.

The targets 106a-106f are bonded to the backing plates 108a-108f by a bonding layer 122. The bonding material may be any conventionally known bonding material known in the art. Exemplary bonding material that may be used to bond the targets 106a-106f to the backing plates 108a-108f are disclosed in U.S. patent application Ser. No. 11/224,221, filed Sep. 12, 2005, which is hereby incorporated by reference in its entirety.

The targets 106a-106f are supported within the apparatus 100 by target support members 124a-124e. The target support members 124a-124e are grounded so that the target support members 124a-124e may function as anodes. Each target support member 124a-124e has a corresponding shield 126a-126e. The shields 126a-126e protect the target support members 124a-124e from unwanted deposition. In one embodiment, the shields 126a-126e are made from the same material as the sputtering target. In another embodiment, the shields 126a-126e are made from stainless steel, bead blasted, and flame sprayed with aluminum or the same material as the sputtering target. The target support members 124a-124e are electrically insulated from each of the targets 106a-106f by a sealing member 130. In one embodiment, the sealing member is an O-ring.

The targets 106a, 106f that are adjacent the chamber walls 116 seal to the chamber wall 116 with a sealing member 130. In one embodiment, the sealing member 130 is an O-ring. The targets 106a, 106f each have a sealing surface 134a, 134f that seals to a sealing surface 136 of the chamber wall 116.

Each target 106a-106f is coupled with a corresponding power source 128a-128f so that each target 106a-106f may be individually powered. By providing a separate power source 128a-128f to each target 106a-106f, the power level to each target 106a-106f may be individually controlled to achieve a uniform deposition. The power source 128a-128f may be DC, AC, pulsed, RF, or a combination thereof.

For example, the chamber walls 116 are grounded and thus function as an anode. The susceptor 102 may also be grounded and function as an anode. Charged particles formed during sputtering will have a tendency to be drawn towards the anode to find a path to ground. When the substrate 104 is formed of an insulative material, the path to ground through the susceptor is effectively blocked by the substrate 104. The charged particles are drawn towards the chamber walls 116 functioning as an anode instead of the substrate 104. Because the particles are drawn towards the chamber walls 116, the plasma may be uneven within the chamber and hence, cause uneven deposition across the substrate 104. The uneven deposition may result in greater deposition on the edge of the substrate 104, corresponding to the chamber walls 116, and less deposition towards the center of the substrate 104 where the anode exists. Increasing the power applied to the targets (i.e., targets 106c, 106d) near the center of the substrate 102 compared to the power applied to the periphery targets (i.e., targets 106a, 106f) may compensate for the effects of the anode drawing the plasma toward the chamber walls 116. The apparatus may be controlled by a controller 132.

Each backing plate 108a-108f and target 106a-106f is electrically coupled with a resistor R₁-R₆. The resistors R₁-R₆ are coupled together through contact point P₁. The resistors R₁-R₆ provide greater flexibility in powering the sputtering targets 106a-106f. For example, the resistors R₁-R₆ resist the amount of power flowing from one sputtering target 106a-106f to another sputtering target 106a-106f and may be set to a predetermined limit. Therefore, power may be applied to a first target (for example target 106a) and then the power applied to each additional target 106b-106f will be set based upon the amount of power allowed to flow through the resistors R₁-R₆. The resistors R₁-R₆ provide the flexibility of using a single power source to supply a specific power to a plurality of targets electrically coupled together.

In another embodiment, the resistors R₁-R₆ provide an additional source of power to each target 106a-106f by coupling power from another target 106a-106f together with the power from the power source 128a-128f of the individual targets 106a-106f. For example, one target 106a may be coupled to DC power source 128a while another target 106b may be coupled to a pulsed or RF power source 128b. The resistors R₁-R₂ may permit the RF or pulsed bias to be superimposed over the DC bias to target 106a to increase the bias voltage and produce more activated species in the plasma. Thus, each target 106a-106f would have its own individual power supply 128a-128f, but also be coupled with a resistor R₁-R₆.

In one embodiment, at least one sputtering target 106a-106f has a different composition from another sputtering target 106a-106f. The composition of each target 106a-106f may be chosen so that when sputtered, a film with a desired composition is formed. By adjusting the power level to each target 106a-106f individually using the resistors R₁-R₆ and individual power sources 128a-128f, a different bias may be applied to each target 106a-106f and hence, to different target compositions. By controlling the power supplied to different targets 106a-106f having different compositions, the composition of the deposited film may be controlled.

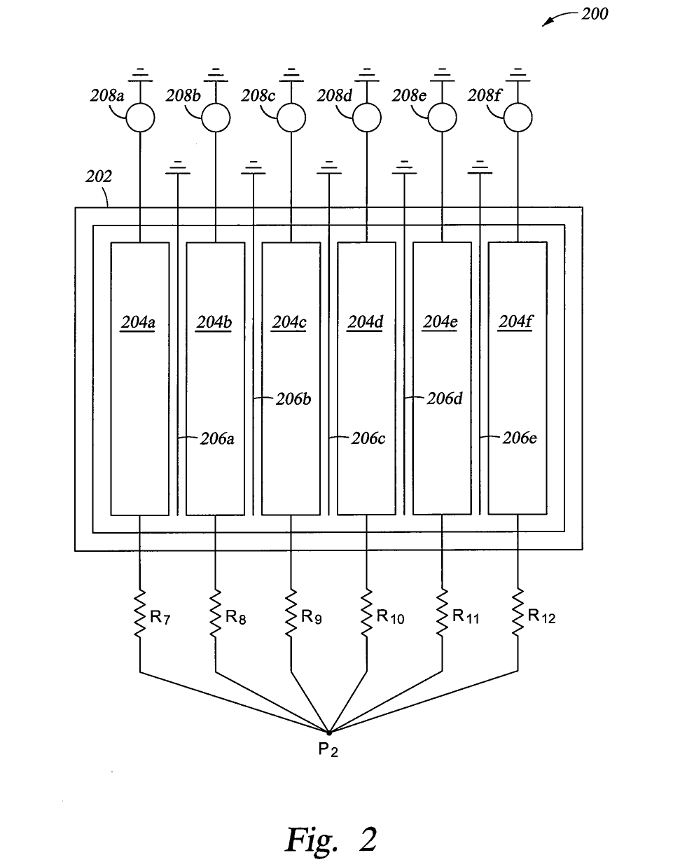

FIG. 2 is a schematic view of the electrical coupling for a target assembly 200 according to one embodiment of the invention. The target assembly 200 includes a single, common backing plate 202 and a plurality of sputtering targets 204a-204f coupled therewith. Grounded anodes 206a-206e may be positioned between adjacent sputtering targets 204a-204f. Each sputtering target 204a-204f may be electrically coupled with an individual power supply 208a-208f. The power source 208a-208f may be DC, AC, pulsed, RF, or a combination thereof. Resistors R₇-R₁₂ are also coupled to each target 204a-204f. The resistors R₇-R₁₂ are coupled together about a common contact point P₂. The resistors R₇-R₁₂ function in a manner similar to that described above in relation to FIG. 1.

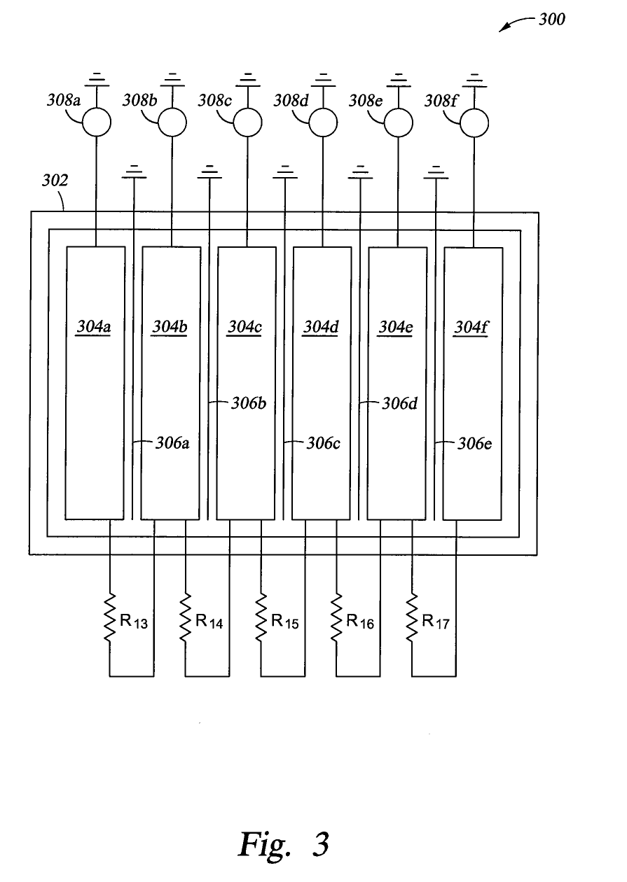

FIG. 3 is a schematic view of the electrical coupling for a target assembly 300 according to another embodiment of the invention. The target assembly 300 includes a single, common backing plate 302 and a plurality of sputtering targets 304a-304f coupled therewith. Grounded anodes 306a-306e may be positioned between adjacent sputtering targets 304a-304f. Each sputtering target 304a-304f may be electrically coupled with an individual power supply 308a-308f. The power source 308a-308f may be DC, AC, pulsed, RF, or a combination thereof. Each sputtering target 304a-304f may be electrically coupled with the adjacent sputtering target 304a-304f through a resistor R₁₃-R₁₇. The resistors R₁₃-R₁₇ function in a manner similar to that described above in relation to FIGS. 1 and 2.

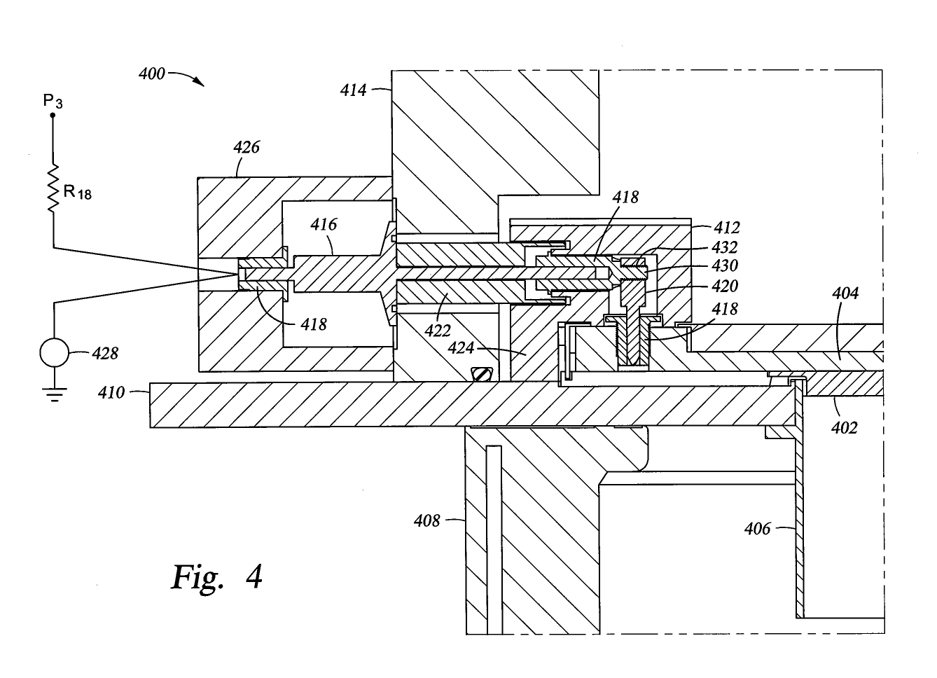

FIG. 4 is a cross sectional view of electrical coupling of a power source to a sputtering target according to one embodiment of the present invention. The apparatus 400 has a chamber wall 408 and a chamber top frame 410. Within the apparatus 400 is a sputtering target 402 and dark space shield 406. The target 402 is coupled with a backing plate 404 by a layer of bonding material (not shown). The backing plate 404 may be cooled with fluid supplied from a cooling manifold 412.

The target 402 may be biased through the backing plate 404. A power source 428 may be electrically coupled with the backing plate 404. The power source 428 may be coupled with the backing plate 404 through an electrical contact assembly 420 that is held in place by an electrical socket 418. An electrical feed through 416 is coupled with the power source 428 and rests in an electrical interface 426. The electrical feed through 416 is also coupled with a resistor R₁₈ which is coupled to a contact point P₃. The electrical feed through 416 is held in place through the electrical interface 426 with an electrical socket 418. The electrical feed through 416 passes through an upper housing 414 of the apparatus 400 and is electrically isolated from the apparatus 400 by an insulation sleeve 422 as it passes through the upper housing 414. The electrical feed through 416 is coupled between an insulating mounting frame 424 and the cooling manifold 412 by an electrical socket 418 to hold the electrical feed through 416 in place. The electrical socket 418 may have a male connector 430 for interfacing with a female connector 432 on the electrical contact assembly 420. the Electrical socket 418 with the male connector 430 interfaces substantially perpendicularly with the female connector 432 of the electrical contact assembly 420.

The electrical contact assembly 420 couples with the backing plate 404 through a hole that is formed through the back surface of the backing plate 404. By providing a substantially perpendicular interface between the electrical socket 418 and the electrical contact assembly 420, valuable processing space may be saved. For example, if the electrical contact assembly 420 and electrical socket 418 with the male connector 430 were to be substantially horizontal in orientation, then the electrical contact assembly 420 needs to either interface the backing plate 404 from a side of the backing plate 404 or interface from the backside with the electrical feed through 416 passing through a roof of the upper housing 414.

For the electrical contact assembly 420 to interface with the backing plate 404 from a side of the backing plate 404, the electrical feed through 416 would rest against the chamber top frame 410. By resting against the top frame, the bottom wall of the electrical interface 426 would need to be eliminated. Additionally, by resting on the chamber top frame 410, the chamber body will be biased during processing because the apparatus 400 and chamber walls 408 may be made of stainless steel.

For the electrical contact assembly 420 to interface with the backing plate 404 from the backside of the backing plate 404, but without a substantially perpendicular interface between the electrical socket 418 and the electrical contact assembly 420, the electrical feed through 416 would be fed through a top of the upper housing 414. Logistically, it would be quite cumbersome to service and/or inspect the electrical feed through 416 and electrical interface 426 when they are fed through the top of the upper housing 414.

Individually powered targets with a resister coupled thereto are beneficial for depositing films on large area substrates. The smaller, strip shaped targets are less expensive than a single, large area target. Additionally, the power to each individual target may be adjusted and controlled. The resistors control the power applied to the targets and may also provide a superimposed power supply to the targets.

While the foregoing is directed to embodiments of the present invention, other and further embodiments of the invention may be devised without departing from the basic scope thereof, and the scope thereof is determined by the claims that follow.

1. An apparatus, comprising:
a plurality of sputtering targets, wherein at least two of the sputtering targets are electrically coupled together with an electrical connection;
one or more resistors coupled with each electrical connection; and
a separate power source coupled with each sputtering target.

2. The apparatus of claim 1, wherein each target has an electrical connection with another target.

3. The apparatus of claim 1, wherein each target is a strip shaped target.

4. The apparatus of claim 1, further comprising:
at least one anode positioned between the targets that are electrically coupled together.

5. The apparatus of claim 1, further comprising:
a plurality of resistors, wherein each sputtering target has a corresponding resistor coupled therewith and wherein each resistor is electrically coupled together at a contact point.

6. The apparatus of claim 1, wherein each sputtering target is electrically coupled with an adjacent sputtering target via the electrical connection.

7. The apparatus of claim 1, wherein at least one power source is a pulsed power source.

8. The apparatus of claim 1, further comprising:
six sputtering targets.

9. A physical vapor deposition method, comprising:
positioning a substrate in a chamber, wherein the chamber comprises a plurality of sputtering targets electrically coupled together with an electrical connection that comprises one or more resistors, and wherein the chamber additionally comprises a separate power source coupled with each target;
controlling the power applied to each target;
sputtering material from the targets; and
depositing the sputtered material on the substrate.

10. The method of claim 9, further comprising:
adjusting the power supplied to each target, wherein the adjusting comprises applying different power levels to adjacent targets.

11. The method of claim 9, wherein the power is pulsed.

12. The method of claim 9, further comprising:
biasing the plurality of sputtering targets, wherein the biasing comprises biasing at least one target as a cathode and at least one target as an anode.

13. An apparatus, comprising:
a sputtering target assembly, the assembly comprising:
at least one backing plate, the backing plate having a back surface; and
at least one sputtering target bonded with the at least one backing plate;
an electrical connection coupled with the sputtering target assembly, the electrical connection comprising:
an electrical feed through substantially perpendicularly coupled with an electrical contact assembly, wherein the electrical contact assembly couples with the at least one backing plate through an electrical connection hole formed in the back surface of the backing plate.

14. The apparatus of claim 13, further comprising:
an insulating sleeve, wherein the electrical feed through is enclosed within the insulating sleeve.

15. The apparatus of claim 13, further comprising:
a resistor electrically coupled with the electrical feed through.

16. The apparatus of claim 13, wherein the electrical connection comprises a male connection coupled with a female connection of the electrical contact assembly.

17. A physical vapor deposition method, comprising:
positioning a substrate in a chamber having at least one target coupled with a backing plate, wherein the chamber comprises an electrical connection coupled with the backing plate, the electrical connection comprising an electrical feed through substantially perpendicularly coupled with an electrical contact assembly, wherein the electrical contact assembly couples with the backing plate through an electrical connection hole formed in a back surface of the backing plate;
controlling the power applied to the target, wherein the controlling comprises coupling the target to a resistor;
sputtering material from the target; and
depositing the sputtered material on the substrate.

18. The method of claim 17, further comprising:
adjusting the power applied to the target.

19. The method of claim 17, wherein the power applied is pulsed.

20. The method of claim 17, further comprising:
providing a cooling fluid to the backing plate.
